(19) United States
(12) Patent Application Publication
(10) Pub. No.: US 2020/0117038 A1
(43) Pub. Date: Apr. 16, 2020

(54) DISPLAY DEVICE, AND METHOD FOR MONITORING CONTACT DEPTH OF A FLEXIBLE PRINTED CIRCUIT BOARD OF THE SAME

(71) Applicant: SAMSUNG DISPLAY CO., LTD., Yongin-si (KR)

(72) Inventors: Taihuem OM, Asan-si (KR); Youngho KIM, Ulsan (KR); Sejin EOM, Cheonan-si (KR)

(21) Appl. No.: 16/512,855

(22) Filed: Jul. 16, 2019

(30) Foreign Application Priority Data
Oct. 15, 2018 (KR) 10-2018-0122303

(51) Int. Cl. G02F 1/1345; H05K 1/11

(52) U.S. Cl. CPC G02F 1/13458; G02F 1/13452; H05K 2201/10128; H05K 2201/098; H05K 1/118

(57) ABSTRACT

A display device includes: a display panel including a pad portion disposed at a non-display area; and a flexible printed circuit board including a contact portion which contacts the pad portion. The flexible printed circuit board includes a scale pattern spaced apart from the contact portion. The scale pattern includes a plurality of scales arranged at a constant interval in a direction parallel to an extending direction of the contact portion. An end portion of the scale pattern is aligned with an end portion of the contact portion on an imaginary line.

This application claims priority to Korean Patent Application No. 10-2018-0122303, filed on Oct. 15, 2018, the content of which in its entirety is herein incorporated by reference.

### BACKGROUND

### 1. Field

Embodiments of the invention relate to a display device in which a contact depth is easily identified or measured when a flexible printed circuit board (“FPCB”) contacts a display panel to be attached thereto in a process of manufacturing the display panel, and to a method of monitoring the contact depth of the FPCB of the display device.

### 2. Discussion of Related Art

A display device may include a driving circuit that drives a display panel, and a flexible printed circuit board (“FPCB”) that is connected to the display panel to transmit a driving signal of the display panel.

In order for the FPCB to be connected to the display panel, a pad area, to which the FPCB is connected, may be defined at an outer edge area of the display panel. The pad area may be exposed to an outside for bonding to the FPCB.

### SUMMARY

In a process of attaching a flexible printed circuit board (“FPCB”) to a pad portion during a manufacturing process of a display device, it is desired for the connection between terminals to be carried out accurately. In some cases, a cell terminal of the pad portion and a connection terminal of the FPCB may be inaccurately connected to each other and may contact each other in a slightly dislocated manner.

In addition, when the FPCB contacts the pad portion, if the contact of the FPCB is insufficient, the pad portion may be broken. On the other hand, if the contact of the FPCB is excessive, burning of the pad portion may be caused.

Accordingly, it is desired to identify a degree of a contact depth of the FPCB when the FPCB is attached to the pad portion.

Embodiments of the invention may be directed to a display device that allows a contact depth to be easily identified when a FPCB contacts a pad portion of a display panel to be attached thereto in a process of manufacturing the display panel, and to a method of monitoring the contact depth of the FPCB of the display device.

According to an embodiment, a display device includes: a display panel including a pad portion disposed at a non-display area; and a FPCB including a contact portion which contacts the pad portion. In such an embodiment, the FPCB includes a scale pattern spaced apart from the contact portion. In such an embodiment, the scale pattern includes a plurality of scales arranged at a constant interval in a direction parallel to an extending direction of the contact portion. In such an embodiment, an end portion of the scale pattern is aligned with an end portion of the contact portion on an imaginary line.

In an embodiment, each of the plurality of scales may have a length substantially the same as the constant interval in the extending direction of the contact portion.

In an embodiment, the plurality of scales may have sizes substantially the same as each other.

In an embodiment, the plurality of scales may have shapes substantially the same as each other.

In an embodiment, each of the plurality of scales may include a material substantially the same as a material of the contact portion.

In an embodiment, each of the plurality of scales may have at least one of shapes of circles, polygons, numbers and letters.

In an embodiment, the pad portion may include a first alignment mark, and the FPCB may include a second alignment mark.

In an embodiment, an end portion of the second alignment mark may be aligned with the end portion of the contact portion and the end portion of the scale pattern on the imaginary line.

In an embodiment, the second alignment mark may be spaced apart from the contact portion and the scale pattern.

In an embodiment, the second alignment mark may be disposed between the contact portion and the scale pattern.

In an embodiment, the second alignment mark and the first alignment mark may be aligned with each other, the contact portion may contact the pad portion, and at least a part of the scale pattern may overlap the pad portion.

In an embodiment, the contact portion may have a contact depth determined based on the number of scales overlapping the pad portion among the plurality of scales.

According to an embodiment, a method of monitoring a contact depth of a FPCB of a display device, the display device including a display panel that includes a pad portion disposed at a non-display area; and the FPCB that includes a contact portion to contact the pad portion and a scale pattern spaced apart from the contact portion, includes contacting the FPCB to the pad portion in a way such that the scale pattern overlaps the pad portion; and determining a contact depth of the FPCB being based on the number of scales overlapping the pad portion among a plurality of scales of the scale pattern.

In an embodiment, the scale pattern may include the plurality of scales arranged at a constant interval in a direction parallel to an extending direction of the contact portion.

In an embodiment, an end portion of the scale pattern may be aligned with an end portion of the contact portion on an imaginary line.

In an embodiment, each of the plurality of scales may have a length substantially the same as the constant interval in the extending direction of the contact portion.

In an embodiment, the plurality of scales may have sizes substantially the same as each other.

In an embodiment, the plurality of scales may have shapes substantially the same as each other.

In an embodiment, each of the plurality of scales may include a material substantially the same as a material of the contact portion.

In an embodiment, each of the plurality of scales may have at least one of shapes of circles, polygons, numbers and letters.

In an embodiment, the pad portion may include a first alignment mark, and the FPCB may include a second alignment mark.

In an embodiment, an end portion of the second alignment mark may be aligned with an end portion of the contact portion and an end portion of the scale pattern on the imaginary line.

In an embodiment, the second alignment mark may be spaced apart from the contact portion and the scale pattern.

In an embodiment, the second alignment mark may be disposed between the contact portion and the scale pattern.

### BRIEF DESCRIPTION OF THE DRAWINGS

A more complete appreciation of the invention will become more apparent by describing in detail embodiments thereof with reference to the accompanying drawings, in which:

FIG. 1 is a view illustrating a configuration of a display device according to an embodiment;

FIG. 2 is a view illustrating a contact portion and a scale pattern of a flexible printed circuit board (“FPCB”) according to an embodiment;

FIG. 3 is a view illustrating an end portion of a contact portion and an end portion of a scale pattern in an FPCB according to an embodiment;

FIGS. 4 to 7 are views illustrating various embodiments of shapes of a scale pattern;

FIGS. 8 and 9 are views illustrating alignment marks provided at an FPCB and a pad portion, respectively, according to an embodiment;

FIG. 10 is a view illustrating an overlap area when an FPCB according to an embodiment is attached to a pad portion; and

FIG. 11 is a flowchart illustrating a method of monitoring a contact depth of an FPCB of a display device according to an embodiment.

### DETAILED DESCRIPTION

Embodiments will now be described more fully hereinafter with reference to the accompanying drawings. Although the invention may be modified in various manners and have several embodiments, embodiments are illustrated in the accompanying drawings and will be mainly described in the specification. However, the scope of the invention is not limited to the embodiments and should be construed as including all the changes, equivalents and substitutions included in the spirit and scope of the invention.

In the drawings, thicknesses of a plurality of layers and areas are illustrated in an enlarged manner for clarity and ease of description thereof. When a layer, area, or plate is referred to as being “on” another layer, area, or plate, it may be directly on the other layer, area, or plate, or intervening layers, areas, or plates may be present therebetween. Conversely, when a layer, area, or plate is referred to as being “directly on” another layer, area, or plate, intervening layers, areas, or plates may be absent therebetween. Further when a layer, area, or plate is referred to as being “below” another layer, area, or plate, it may be directly below the other layer, area, or plate, or intervening layers, areas, or plates may be present therebetween. Conversely, when a layer, area, or plate is referred to as being “directly below” another layer, area, or plate, intervening layers, areas, or plates may be absent therebetween.

The spatially relative terms “below”, “beneath”, “lower”, “above”, “upper” and the like, may be used herein for ease of description to describe the relations between one element or component and another element or component as illustrated in the drawings. It will be understood that the spatially relative terms are intended to encompass different orientations of the device in use or operation, in addition to the orientation illustrated in the drawings. For example, in a case where a device illustrated in the drawing is turned over, the device positioned “below” or “beneath” another device may be placed “above” another device. Accordingly, the illustrative term “below” may include both the lower and upper positions. The device may also be oriented in the other direction and thus the spatially relative terms may be interpreted differently depending on the orientations.

Throughout the specification, when an element is referred to as being “connected” to another element, the element is “directly connected” to the other element, or “electrically connected” to the other element with one or more intervening elements interposed therebetween. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” “At least one of A and B” means “A and/or B.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third,” and the like may be used herein to describe various elements, these elements should not be limited by these terms. These terms are only used to distinguish one element from another element. Thus, “a first element” discussed below could be termed “a second element” or “a third element,” and “a second element” and “a third element” may be termed likewise without departing from the teachings herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system).

Unless otherwise defined, all terms used herein (including technical and scientific terms) have the same meaning as commonly understood by those skilled in the art to which this invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined at the specification.

Some of the parts which are not associated with the description may not be provided in order to specifically describe embodiments of the invention and like reference numerals refer to like elements throughout the specification.

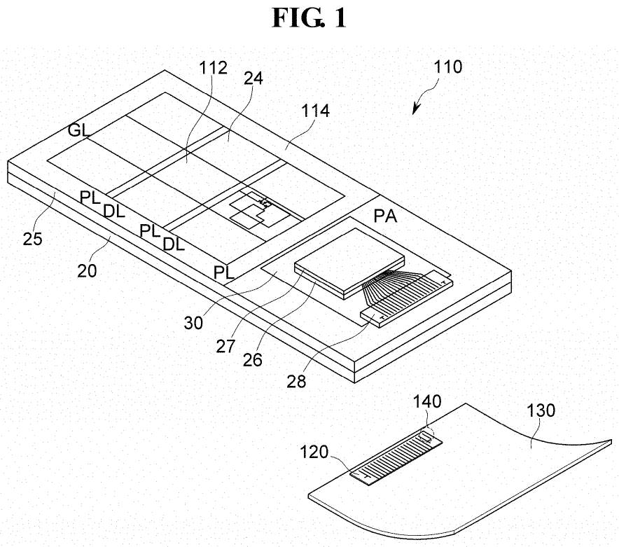

Hereinafter, embodiments of a display device and a method of monitoring a contact depth of a flexible printed circuit board (“FPCB”) of the display device will be described in detail with reference to FIGS. 1 to 11.

FIG. 1 is a view illustrating a configuration of a display device according to an embodiment.

Referring to FIG. 1, an embodiment of a display device may include a display panel 110 that includes a pad portion 30 disposed at a non-display area 114; and an FPCB 130 that includes a contact portion 120 to contact the pad portion 30.

The FPCB 130 may include a scale pattern 140 that is spaced apart from the contact portion 120. The scale pattern 140 may include a plurality of scales.

The display panel 110 may include a display area (“AA”) 112 and the non-display area (“NA”) 114. In an embodiment, the display panel 110 may include the display area 112, at which an encapsulating protection layer 25 is attached on a first substrate 20 and images are displayed on the encapsulating protection layer 25; and the non-display area 114 which is an area other than the display area 112.

The first substrate 20 includes low temperature poly-silicon (“LTPS”), and the encapsulating protection layer 25 seals a light emitting portion 24, at which an organic light emitting layer is disposed, to prevent moisture and oxygen from infiltrating therethrough.

The light emitting portion 24 is disposed in the display area 112, and a plurality of gate lines GL, a plurality of data lines DL and a plurality of power lines PL cross each other to define pixels.

The pad portion 30 is provided at a pad area PA of the non-display area 114. The pad portion 30 is connected to the plurality of gate lines GL and the plurality of data lines DL in the display area 112, and is electrically connected to a driving integrated circuit (“IC”) 27. The driving IC 27 is disposed on the encapsulating protection layer 25, and is electrically connected the pad portion 30 during a pressure bonding process using an anisotropic conductive film 26.

The pad portion 30 contacts the contact portion 120 of the FPCB 130 through a connection portion 28. The contact portion 120 of the FPCB 130 may contact and be attached to the connection portion 28 of the pad portion 30 using an adhesive resin.

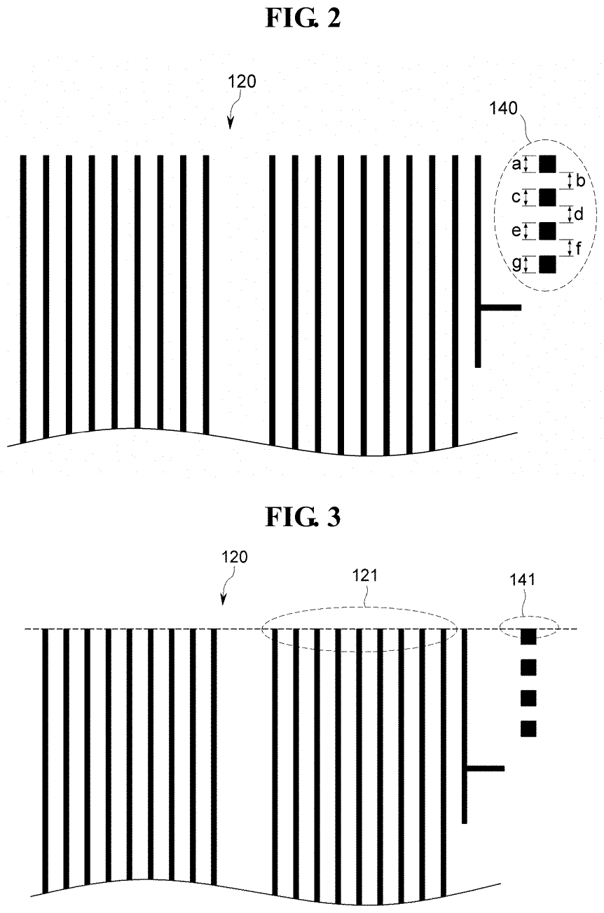

FIG. 2 is a view illustrating a contact portion and a scale pattern of an FPCB according to an embodiment.

Referring to FIG. 2, the contact portion 120 of the FPCB 130 may be spaced apart from the scale pattern 140 by a predetermined distance.

The scale pattern 140 may include a plurality of scales that are arranged at a substantially same interval b, d and f (i.e., at a constant or regular interval) in a direction parallel to a length direction of the contact portion 120.

The contact portion 120 may include a plurality of terminal patterns that contact the connection portion 28 of the pad portion 30. The plurality of terminal patterns may be arranged at a predetermined interval corresponding to a plurality of contact patterns of the connection portion 28 of the pad portion 30. As used herein, each of the scales may include a material substantially the same as a material included in the plurality of terminal patterns of the contact portion 120. When the plurality of terminal patterns include a conductive metal, the plurality of scales may also include the same conductive metal as the plurality of terminal patterns. Accordingly, in such an embodiment, manufacturing costs of the contact portion 120 and the scale pattern 140 may be reduced by manufacturing the contact portion 120 and the scale pattern 140 using a same material.

Each of the plurality of scales may have a length (a, c, e or g) the same as each other (i.e., a=c=e=g), and the length of each of the plurality of scales is substantially the same as each of the intervals (b, d and f) thereof in an extending direction of the contact portion 120. In one embodiment, for example, each of the plurality of scales may have a substantially same length of about 100 micrometers (μm). In such an embodiment, a length of each of the plurality of scales may be about 100 μm, thus satisfying the following equation: a=c=e=g=100 μm.

In an embodiment, sizes of the plurality of scales may be substantially the same as each other, but not being limited thereto. In an alternative embodiment, the plurality of scales may not have a same size as each other, but in such an embodiment, all of the plurality of scales may each have a substantially same length (a=c=e=g) in a length direction.

In an embodiment, shapes of the plurality of scales may be substantially the same as each other, but not being limited thereto. In an alternative embodiment, the plurality of scales may not have the same shape as each other, but in such an embodiment, all of the plurality of scales may each have a substantially same length (a=c=e=g).

In an embodiment, each of the plurality of scales has a substantially same length (a=c=e=g) in a length direction, and the intervals b, d and f between the plurality of scales may be substantially the same as each other (b=d=f). In one embodiment, for example, each of the lengths (a, c, e and g) of the plurality of scales is about 100 μm, and each of the intervals (b, d and f) between the plurality of scales may be about 100 μm.

The respective lengths (a, c, e and g) of the plurality of scales are substantially the same as each other (i.e., a=c=e=g), the intervals (b, d and f) between the plurality of scales are substantially the same as each other (i.e., b=d=f), and each of the lengths (a, c, e and g) is substantially the same as each of the intervals (b, d and f) [i.e., (b=d=f)=(a=c=e=g)].

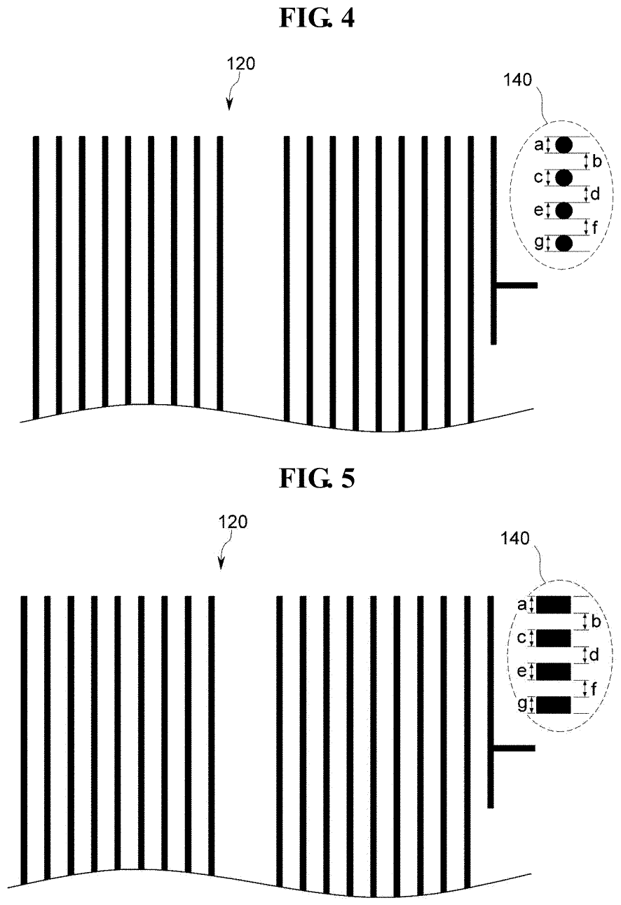

FIG. 3 is a view illustrating an end portion of a contact portion and an end portion of a scale pattern in an FPCB according to an embodiment.

Referring to FIG. 3, in an embodiment the FPCB 130, an end portion 121 of the contact portion 120 and an end portion 141 of the scale pattern 140 may be aligned with each other on a substantially same imaginary line.

In such an embodiment, the contact portion 120 of the FPCB 130 includes the plurality of terminal patterns, and the end portions 121 for the plurality of terminal patterns and the end portion 141 of the scale pattern 140 are aligned with each other or located on a substantially same imaginary line.

In such an embodiment, the scale pattern 140 serves as a measuring ruler for measuring a contact depth of the contact portion 120, and the contact portion 120 serves as a measurement target.

In an embodiment, the end portion 121 of the contact portion 120 and the end portion 141 of the scale pattern 140 are located on a substantially same imaginary line crossing an extending direction of the terminal patterns such that a contact depth of the contact portion 120 may be measured accurately when the contact portion 120 contacts the connection portion 28 of the pad portion 30. In such an embodiment, a start point of the measuring ruler and a start point of the measurement target are desired to be the same as each other to measure the contact depth of the contact portion 120 accurately. Accordingly, in such an embodiment, the end portion 141 of the scale pattern 140, which corresponds to the start point of the measuring ruler, and the end portion 121 of the contact portion 120, which corresponds to the start point of the measurement target, are located on a substantially same line.

In an embodiment, when the FPCB 130 is attached to the pad portion 30, the plurality of terminal patterns of the contact portion 120 overlap the plurality of contact patterns of the connection portion 28, and the contact depth of the contact portion 120 may be identified by measuring an overlap length of the overlap portion. In such an embodiment, the contact portion 120 of the FPCB 130 also overlaps the connection portion 28 of the pad portion 30.

The overlap length of the contact portion 120 is measured from the end portion 121 of the contact portion 120.

In such an embodiment, as described above, the scale pattern 140 may serve as a measuring ruler. In such an embodiment, the overlap length of the contact portion 120 is measured by measuring the number of the scales that are overlapped or covered by the plurality of contact patterns of the connection portion 28 among the plurality of scales arranged at a predetermined interval with a predetermined length from a line substantially the same as a line on which the end portion 121 of the contact portion 120 is located.

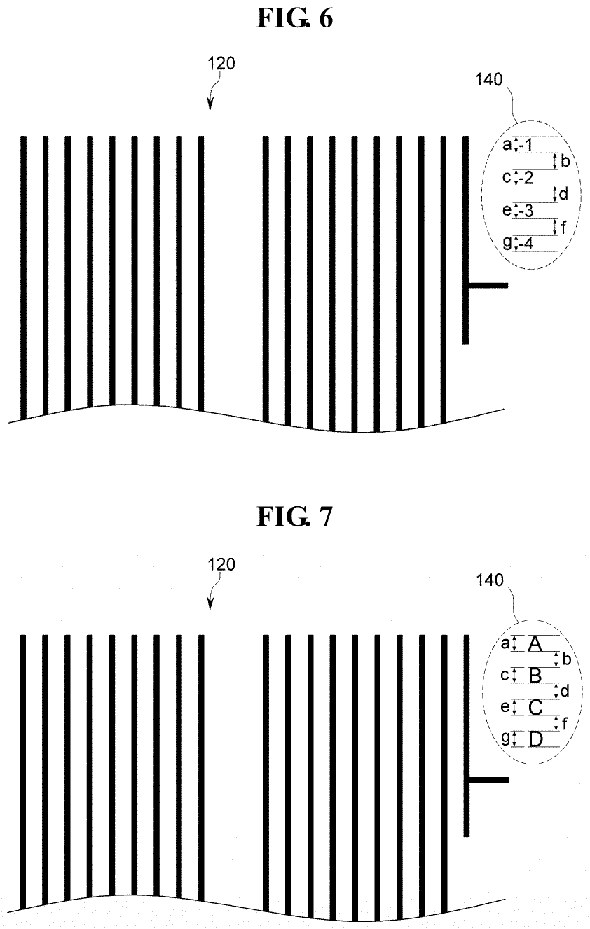

FIGS. 4 to 7 are views illustrating various embodiments of shapes of a scale pattern.

Referring to FIG. 4, an embodiment of the scale pattern 140 may be in a shape selected from shapes of circles, polygons, numbers and letters, e.g., a circular shape.

In such an embodiment, as shown in FIG. 4, each of a first scale, a second scale, a third scale and a fourth scale may have a circular shape having a substantially same diameter as each other or a substantially same radius as each other.

In an alternative embodiment, the plurality of scales, each having a circular shape, may not have a substantially same diameter or a substantially same radius, but in such an embodiment, all of the plurality of scales may have a substantially same length in a direction substantially the same as the length (or extending) direction of the contact portion 120.

In an embodiment where the plurality of scales, each having a circular shape, have a substantially same length in a direction substantially the same as the length direction of the contact portion 120, the plurality of scales may have circular shapes having sizes different from each other in a width direction perpendicular to the length direction. In such an embodiment, all of the plurality of scales may each be spaced apart from one another at a substantially same interval (i.e., b=d=f).

In an embodiment, as described above with reference to FIG. 4, the first scale, the second scale, the third scale and the fourth scale, each having a circular shape, may all have a substantially same length (i.e., a=c=e=g) and a substantially same interval (i.e., b=d=f).

Referring to FIG. 5, an embodiment of the scale pattern 140 may be in a shape selected from shapes of circles, polygons, numbers and letters, e.g., a polygonal shape.

In such an embodiment, as illustrated in FIG. 5, each of a first scale, a second scale, a third scale and a fourth scale may have, for example, a quadrangular shape (e.g., a rectangular shape).

Lengths of two sides of each of the scales, having a rectangular shape, that face each other are substantially the same as each other, and lengths of two sides thereof parallel to the length direction of the contact portion 120 may be shorter than lengths of the other two sides thereof.

All of the scales, each having a rectangular shape, may have a substantially same length (i.e., a=c=e=g) in a direction substantially the same as the length direction of the contact portion 120, and may be arranged at a substantially same interval (i.e., b=d=f).

In an alternative embodiment, lengths of two sides of each of the scales may be different from each other. In such an embodiment, however, all of the scales have a substantially same length (i.e., a=c=e=g) in a direction substantially the same as the length direction of the contact portion 120, and may each be arranged at a substantially same interval (i.e., b=d=f).

In another alternative embodiment, each of the scales may have a rhombic shape or a trapezoidal shape in which lengths of two facing sides are not the same as each other. In such an embodiment, however, all of the scales have a substantially same length (i.e., a=c=e=g) in a direction substantially the same as the length direction of the contact portion 120. In such an embodiment, all of the scales may each be arranged at a substantially same interval (i.e., b=d=f).

In an embodiment, as described above with reference to FIG. 5, all of the first scale, the second scale, the third scale and the fourth scale, each having a rectangular shape, may have a substantially same length (i.e., a=c=e=g), and may also be arranged at a substantially same interval (i.e., b=d=f).

Referring to FIG. 6, an embodiment of the scale pattern 140 may be in a shape selected from shapes of circles, polygons, numbers and letters, e.g., a numerical shape.

In an embodiment, as shown in FIG. 6, all of a first scale “−1,” a second scale “−2,” a third scale “−3,” and a fourth scale “−4” may have a substantially same length (a=c=e=g) in a direction substantially the same as the length direction of the contact portion 120.

In such an embodiment, all of the first scale “−1,” the second scale “−2,” the third scale “−3,” and the fourth scale “−4” may be arranged at a substantially same interval (i.e., b=d=f).

In such an embodiment, all of the first scale “−1,” the second scale “−2,” the third scale “−3,” and the fourth scale “−4” may have a substantially same size as each other, and may be in a substantially same font as each other.

In an alternative embodiment, sizes of the plurality of scales “−1,” “−2,” “−3,” and “−4,” each having a numerical shape as shown in FIG. 6, may be different from each other. In such an embodiment, however, the plurality of scales “−1,” “−2,” “−3,” and “−4” may have a substantially same length (i.e., a=c=e=g) in a direction substantially the same as the length direction of the contact portion 120, and may each be arranged at a substantially same interval (i.e., b=d=f).

In another alternative embodiment, fonts of the plurality of scales “−1,” “−2,” “−3,” and “−4,” each having a numerical shape as shown in FIG. 6, may be different from each other. In such an embodiment, however, the plurality of scales “−1,” “−2,” “−3,” and “−4” may have a substantially same length (i.e., a=c=e=g) in a direction substantially the same as the length direction of the contact portion 120, and may each be arranged at a substantially same interval (i.e., b=d=f).

In an embodiment, as described above with reference to FIG. 6, each of the plurality of scales “−1,” “−2,” “−3,” and “−4” may have a numerical shape of a substantially same thickness, and is arranged at a substantially same interval (b=d=f) as well.

In another embodiment, thicknesses of the numerical shapes of the plurality of scales “−1,” “−2,” “−3,” and “−4” in FIG. 6 may be different from each other. In such an embodiment, however, the plurality of scales “−1,” “−2,” “−3,” and “−4” have a substantially same length (a=c=e=g) in a direction substantially the same as the length direction of the contact portion 120, and are each arranged at a substantially same interval (b=d=f).

Referring to FIG. 7, an embodiment of the scale pattern 140 may be in a shape selected from shapes circles, polygons, numbers and letters, e.g., a letter shape.

In an embodiment, as shown in FIG. 7, all of a first scale “A,” a second scale “B,” a third scale “C,” and a fourth scale “D” may have a substantially same length (i.e., a=c=e=g) in a direction substantially the same as the length direction of the contact portion 120.

In such an embodiment, the first scale “A,” the second scale “B,” the third scale “C,” and the fourth scale “D” may be arranged at a substantially same interval (i.e., b=d=f).

In such an embodiment, all of the first scale “A,” the second scale “B,” the third scale “C,” and the fourth scale “D” may have a substantially same size as each other, and may have a substantially same font as each other.

In an alternative embodiment, sizes of the plurality of scales “A,” “B,” “C,” and “D,” each having a letter shape as shown in FIG. 7 may be different from each other. In such an embodiment, however, the plurality of scales “A,” “B,” “C,” and “D” may have a substantially same length (i.e., a=c=e=g) in a direction substantially the same as the length direction of the contact portion 120, and may each be arranged at a substantially same interval (i.e., b=d=f).

In another alternative embodiment, fonts of the plurality of scales “A,” “B,” “C,” and “D,” each having a letter shape as shown in FIG. 7 may be different from each other. In such an embodiment, however, the plurality of scales “A,” “B,” “C,” and “D” may have a substantially same length (i.e., a=c=e=g) in a direction substantially the same as the length direction of the contact portion 120, and may each be arranged at a substantially same interval (i.e., b=d=f).

In an embodiment, as described above with reference to FIG. 7, each of the plurality of scales “A,” “B,” “C,” and “D” may have a letter shape of a substantially same thickness, and is arranged at a substantially same interval (i.e., b=d=f) as well.

In another alternative embodiment, thicknesses of the letter shapes of the plurality of scales “A,” “B,” “C,” and “D” in FIG. 7 may be different from each other. In such an embodiment, however, the plurality of scales “A,” “B,” “C,” and “D” have a substantially same length (i.e., a=c=e=g) in a direction substantially the same as the length direction of the contact portion 120, and are each arranged at a substantially same interval (i.e., b=d=f).

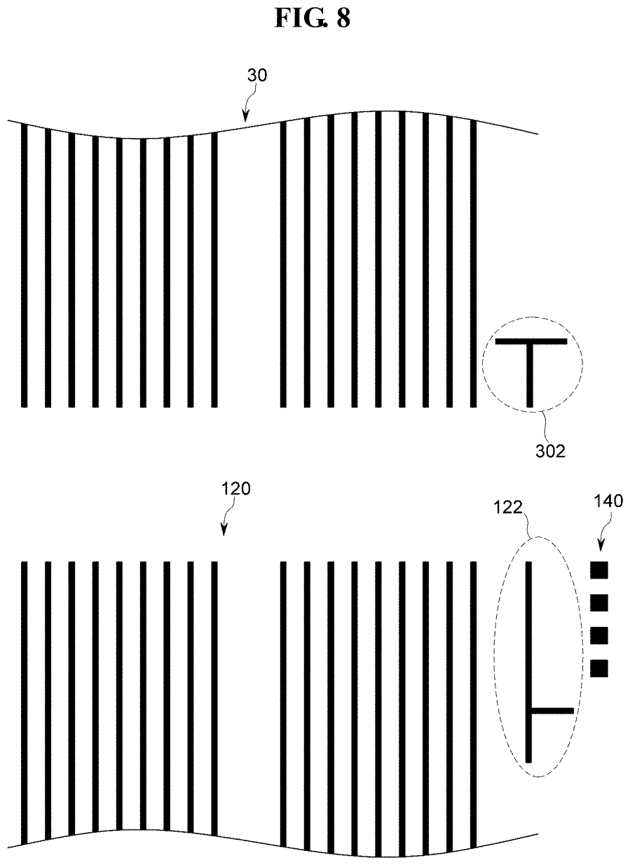

FIGS. 8 and 9 are views illustrating alignment marks provided at an FPCB and a pad portion, respectively, according to an embodiment.

According to an embodiment, referring to FIGS. 8 and 9, the pad portion 30 may include a first align mark 302, and the FPCB 130 may include a second alignment mark 122.

In an embodiment, the first alignment mark 302 having, for example, a “⊥” shape or a “ [symbol] ” shape may be disposed at the pad portion 30 at a location spaced apart from the plurality of contact patterns of the connection portion 28 by a predetermined distance.

In an embodiment, the second alignment mark 122 having, for example, a “├” shape may be disposed at the FPCB 130 at a location spaced apart from the plurality of terminal patterns of the contact portion 120 by a predetermined distance.

The second alignment mark 122 may be disposed between the contact portion 120 and the scale pattern 140.

The second alignment mark 122 may be spaced apart from the contact portion 120 and the scale pattern 140.

The first alignment mark 302 and the second alignment mark 122 may be provided so that the contact portion 120 of the FPCB 130 may not be dislocated from the connection portion 28 of the pad portion 30 when the FPCB 130 is attached to the connection portion 28 of the pad portion 30.

In such an embodiment, as the first alignment mark 302 overlaps the second alignment mark 122, the plurality of terminal patterns at the contact portion 120 may be aligned with the plurality of contact patterns of the connection portion 28 in a one-to-one correspondence without being dislocated from each other.

In such an embodiment, as illustrated in FIG. 9, an end portion 123 of the second alignment mark 122 may be located on a line substantially the same as a line on which the end portion 121 of the contact portion 120 and the end portion 141 of the scale pattern 140 are located.

Accordingly, the contact portion 120 of the FPCB 130 may correspondingly contact the connection portion 28 of the pad portion 30, when the FPCB 130 is attached to the pad portion 30.

In such an embodiment, the plurality of terminal patterns of the contact portion 120 and the plurality of contact patterns of the connection portion 28 may correspondingly contact each other in a one-to-one correspondence without being dislocated from each other.

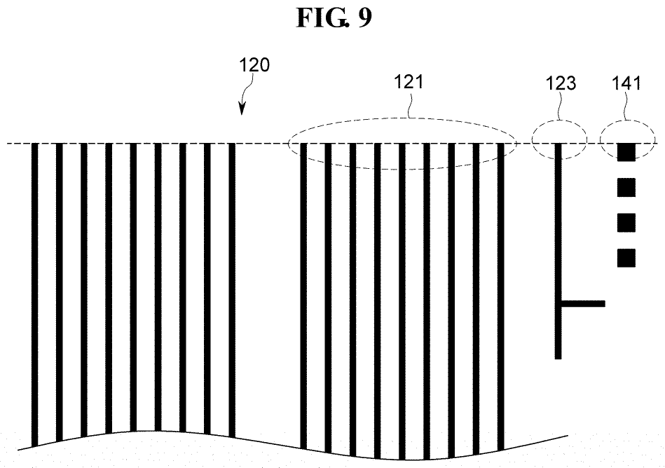

FIG. 10 is a view illustrating an overlap area when an FPCB according to an embodiment is attached to a pad portion.

Referring to FIG. 10, an embodiment of the FPCB 130 may allow the contact portion 120, including the plurality of terminal patterns, to contact the connection portion 28 of the pad portion 30, including the plurality of contact patterns, in a corresponding manner with respect to the second alignment mark 122.

In such an embodiment, as illustrated in FIG. 10, when the FPCB 130 contacts the pad portion 30, the second alignment mark 122 and the first alignment mark 302 are aligned with each other, and the contact portion 120 overlaps and contacts the connection portion 28 of the pad portion 30.

In such an embodiment, the scale pattern 140 of the FPCB 130 also overlaps the pad portion 30.

Accordingly, the plurality of terminal patterns of the contact portion 120 and the plurality of contact patterns of the connection portion 28 may correspondingly contact each other in an overlap manner without being dislocated from each other.

As the FPCB 130 is attached to the pad portion 30, an overlap area 1010 is defined between the contact portion 120 of the FPCB 130 and the connection portion 28 of the pad portion 30, and an overlap area 1010 is also defined between the pad portion 30 and the scale pattern 140.

Accordingly, a contact depth dp of the contact portion 120 may be determined according to the number of scales of the scale pattern 140 overlapping the pad portion 30.

In one embodiment, for example, as illustrated in FIG. 10, three scales may overlap the pad portion 30 in the overlap area 1010 between the pad portion 30 and the scale pattern 140. In a case where, for example, a length of a scale in a direction substantially the same as the length direction of the contact portion 120 is about 100 μm and an interval between adjacent ones of the scales is about 100 μm, the contact depth dp is about 500 μm.

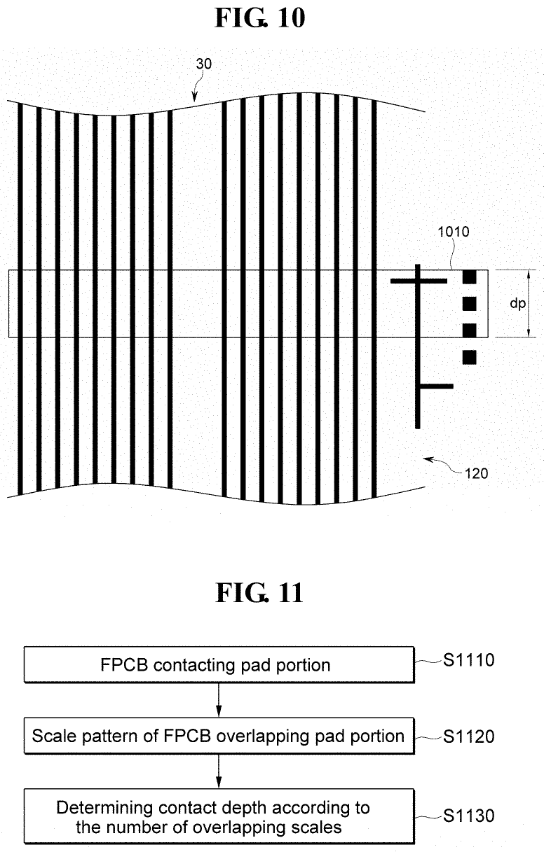

FIG. 11 is a flowchart illustrating a method of monitoring a contact depth of an FPCB of a display device according to an embodiment.

Referring to FIG. 11, in an embodiment of a method of monitoring a contact depth of an FPCB of a display, the FPCB 130 firstly contacts the pad portion 30 (S1110).

In such an embodiment, the contact portion 120 of the FPCB 130 that includes the plurality of terminal patterns correspondingly contact the connection portion 28 of the pad portion 30 that includes the plurality of contact patterns by aligning the second alignment mark 122 with the first alignment mark 302.

Then, the scale pattern 140 overlaps the pad portion 30 (S1120).

In such an embodiment, when the FPCB 130 overlaps the pad portion 30, the scale pattern 140, which is spaced apart from the contact portion 120 of the FPCB 130 by a predetermined distance, also overlaps the pad portion 30.

In such an embodiment, the scale pattern 140 includes the plurality of scales that are arranged at a substantially same interval in a direction parallel to the length direction of the contact portion 120.

Accordingly, a part of the plurality of scales overlap the pad portion 30.

Next, the contact depth of the FPCB 130 is determined according to the number of scales of the scale pattern 140 that overlap the pad portion 30 (S1130).

In one embodiment, for example, when the plurality of terminal patterns of the contact portion 120 of the FPCB 130 contact the plurality of contact patterns of the connection portion 28 of the pad portion 30, three scales of the scale pattern 140 may overlap the pad portion 30, as illustrated in FIG. 10.

In a case where, for example, three scales of the scale pattern 140 overlap the pad portion 30, as illustrated in FIG. 10, with a length of a scale being about 100 μm, an interval between adjacent ones of the scales being about 100 μm, the contact depth dp of the FPCB 130 is about 500 μm. That is, the contact depth dp of the FPCB 130 may be obtained as 500 μm by adding 300 μm of the three scales to 200 μm of the two intervals.

As such, according to an embodiment, it is possible to realize a display device and a method of monitoring a contact depth of an FPCB of the display device in which a contact depth may be easily identified when the FPCB contacts and is attached to a pad portion of a display panel in a process of manufacturing the display panel.

As set forth hereinabove, according to one or more embodiments of the invention, a contact depth of an FPCB may be easily identified when the FPCB contacts a display panel to be attached thereto in a process of manufacturing the display panel.

As such, since the contact depth of the FPCB may be easily identified, breakage of a pad portion that may be caused when a contact of the FPCB is insufficient may be effectively prevented, and burning of the pad portion that may be caused when the contact of the FPCB is excessive may be effectively prevented.

While the invention has been illustrated and described with reference to the embodiments thereof, it will be apparent to those of ordinary skill in the art that various changes in form and detail may be made thereto without departing from the spirit and scope of the invention.

What is claimed is:

1. A display device comprising:
a display panel comprising a pad portion disposed at a non-display area; and
a flexible printed circuit board comprising a contact portion which contacts the pad portion,
wherein the flexible printed circuit board comprises a scale pattern spaced apart from the contact portion,
the scale pattern comprises a plurality of scales arranged at a constant interval in a direction parallel to an extending direction of the contact portion, and
an end portion of the scale pattern is aligned with an end portion of the contact portion on an imaginary line.

2. The display device of claim 1, wherein each of the plurality of scales has a length substantially the same as the constant interval in the extending direction of the contact portion.

3. The display device of claim 1, wherein the plurality of scales has sizes substantially the same as each other.

4. The display device of claim 1, wherein the plurality of scales has shapes substantially the same as each other.

5. The display device of claim 1, wherein each of the plurality of scales comprises a material substantially the same as a material of the contact portion.

6. The display device of claim 1, wherein each of the plurality of scales has at least one of shapes of circles, polygons, numbers and letters.

7. The display device of claim 1, wherein
the pad portion comprises a first alignment mark, and
the flexible printed circuit board comprises a second alignment mark.

8. The display device of claim 7, wherein an end portion of the second alignment mark is aligned with the end portion of the contact portion and the end portion of the scale pattern on the imaginary line.

9. The display device of claim 7, wherein the second alignment mark is spaced apart from the contact portion and the scale pattern.

10. The display device of claim 7, wherein the second alignment mark is disposed between the contact portion and the scale pattern.

11. The display device of claim 7, wherein
the second alignment mark and the first alignment mark are aligned with each other,
the contact portion contacts the pad portion, and
at least a part of the scale pattern overlaps the pad portion.

12. The display device of claim 8, wherein the contact portion has a contact depth determined based on the number of scales overlapping the pad portion among the plurality of scales.

13. A method of monitoring a contact depth of a flexible printed circuit board of a display device, the display device comprising a display panel which comprises a pad portion disposed at a non-display area; and the flexible printed circuit board which comprises a contact portion contacting the pad portion and a scale pattern spaced apart from the contact portion, the method comprising:
contacting the flexible printed circuit board to the pad portion in a way such that the scale pattern overlaps the pad portion; and
determining a contact depth of the flexible printed circuit board based on the number of scales overlapping the pad portion among a plurality of scale patterns of the scale pattern.

14. The method of claim 13, wherein the scale pattern comprises the plurality of scales arranged at a constant interval in a direction parallel to an extending direction of the contact portion.

15. The method of claim 13, wherein an end portion of the scale pattern is aligned with an end portion of the contact portion on an imaginary line.

16. The method of claim 14, wherein each of the plurality of scales has a length substantially the same as the constant interval in the extending direction of the contact portion.

17. The method of claim 14, wherein the plurality of scales has sizes substantially the same as each other.

18. The method of claim 14, wherein the plurality of scales has shapes substantially the same as each other.

19. The method of claim 13, wherein each of the plurality of scales comprises a material substantially the same as a material of the contact portion.

20. The method of claim 13, wherein each of the plurality of scales has at least one of shapes of circles, polygons, numbers and letters.

21. The method of claim 13, wherein
the pad portion comprises a first alignment mark, and
the flexible printed circuit board comprises a second alignment mark.

22. The method of claim 21, wherein an end portion of the second alignment mark is aligned with an end portion of the contact portion and an end portion of the scale pattern on the imaginary line.

23. The method of claim 21, wherein the second alignment mark is spaced apart from the contact portion and the scale pattern.

24. The method of claim 21, wherein the second alignment mark is disposed between the contact portion and the scale pattern.
